(19) United States
(12) Patent Application Publication
(10) Pub. No.: US 2004/0266174 A1
(43) Pub. Date: Dec. 30, 2004

(54) Method and apparatus of preventing tungsten pullout during tungsten chemical mill processing

(76) Inventors: Chin-Tien Yang, Hsin-Chu (TW); Juei-Kuo Wu, Hsin-Chu (TW); Dian-Hua Chen, Hsin-Chu (TW); Huan-Chi Tseng, Hsin-Chu (TW)

Correspondence Address: SLATER & MATSIL, L.L.P., 17950 PRESTON ROAD, SUITE 1000, DALLAS, TX, 75252, US

(21) Appl. No.: 10/608,347

(22) Filed: Jun. 27, 2003

(51) Int. Cl. H01L 21/4763; H01L 21/44

(52) U.S. Cl. 438/629; 438/633; 438/626; 438/627; 438/643; 438/645

(57) ABSTRACT

A method of reducing or substantially eliminating the number of tungsten plug pullouts and consequential chip failures by controlling the CMP step of removing the overfilled tungsten so as to leave a thin layer of tungsten instead of continuing the removal down to the top surface of the dielectric layer.

### TECHNICAL FIELD

The present invention relates to methods of interconnecting layers of semiconductors on a wafer substrate by tungsten plugs and more particularly a method of producing tungsten plugs or vias filled with tungsten for connecting semiconductor layers having reduced pullout characteristics during the chemical milling processing of a 300 μm wafer.

### BACKGROUND

As is well known by those skilled in the art, increasing yield is one of the primary goals of any change in the fabrication of semiconductors devices. For example only, if a 200 μm silicon wafer has space for 100 IC's or integrated circuits, the amount of yield would be 100 percent if all 100 IC's passed all of the functional and operational tests. Although a 100 percent pass rate would be unusual, there are other ways to reduce costs. For example, if a 200 μm wafer having an area of 31,400 square μm=(πd²/4) then a 300 μm wafer having 70,650 square μm should produce over 200 similar IC's. In other words, over twice the number of IC's. Since the process times and steps for a 200 μm wafer and a 300 μm wafer would be substantially the same, it is obvious that if the cost of a 300 μm wafer is proportional to the area increase over a 200 μm wafer, then increasing the wafer size should reduce manufacturing costs. Consequently, 300 μm wafers are available at competitive prices and many, if not most, manufacturing processes are switching over to 300 μm wafers.

Unfortunately, as always seems to be the case, an improvement in manufacturing techniques in one area either amplifies minor existing yield problems or introduces completely new yield problems. One yield problem that has become significant with 300 μm wafers is the “pullout” during CMP (chemical mill processing) of tungsten (W) plugs used to connect circuit levels in a multilevel IC.

The problem was almost non-existent with the prior art 200 μm wafers, but is not at all unusual while processing 300 μm wafers. The problem is believed to result because of differences in thermal expansion of materials deposited on the silicon wafer. It is well-known that films deposited over silicon always cause some sort of stress. As examples, depositing an oxide film typically causes compressive stress whereas depositing a metal film over silicon typically causes tensile stress. The resulting stress usually manifests itself as wafer warpage, and increasing the wafer size from 200 μm to 300 μm has increased the wafer warpage significantly enough to cause the tungsten plug to pullout or pull-up at the center of the larger wafer.

A process that will eliminate or significantly reduce the tungsten plug pullout would be advantageous.

### SUMMARY OF THE INVENTION

The present invention provides methods and apparatus for reducing the failure of tungsten plugs used to connect layers of semiconductor elements in an electrical or semiconductor substrate. According to the invention, there is provided a substrate which has a lower portion, which may comprise one or more layers of metallization or semiconductor elements. A selected material, such as for example, a dielectric or an insulating material is deposited over the lower portion and has a top surface which defines an aperture in the selected material which extends from the top surface toward the lower portion. Tungsten is deposited over the top surface of the selected material so as to completely fill the aperture. According to one embodiment, a liner material, or glue, is deposited in the aperture and over the top surface of the selected material before the tungsten is deposited. The layer of material is then polished to remove a top portion of the layer, but the polishing is stopped so as to leave a thin or reduced layer of tungsten such as between about 0.3 μm and 0.01 μm. Thus, in contrast to the prior art, which polished the tungsten layer so that it was completely removed, the method of the present invention stops short such that a thin layer of tungsten remains. A contact area of a suitable material such as aluminum, copper, an alloy of aluminum and copper or other conductive material is then deposited and pattern-etched so that it lies over at least a portion of the aperture and such that the tungsten filling the via or trench is in electrical contact with the contact area.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 shows a typical layout of a multiplicity of electronic chips or IC's on a wafer;

FIG. 2 illustrates a typical tungsten plug pullout on a 300 μm wafer;

FIGS. 3A and 3B are cross-sectional views illustrating the prior art process steps of providing tungsten plugs for interconnecting layers of semiconductor devices;

FIG. 3C shows the cross-sectional view of FIG. 3B with a via and trench tungsten plug that has been pulled out of the surrounding material such as during the chemical milling process of the prior art methods; and

FIG. 4 and FIG. 5 illustrate the fabrication process of providing tungsten vias and trench plugs according to the teachings of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

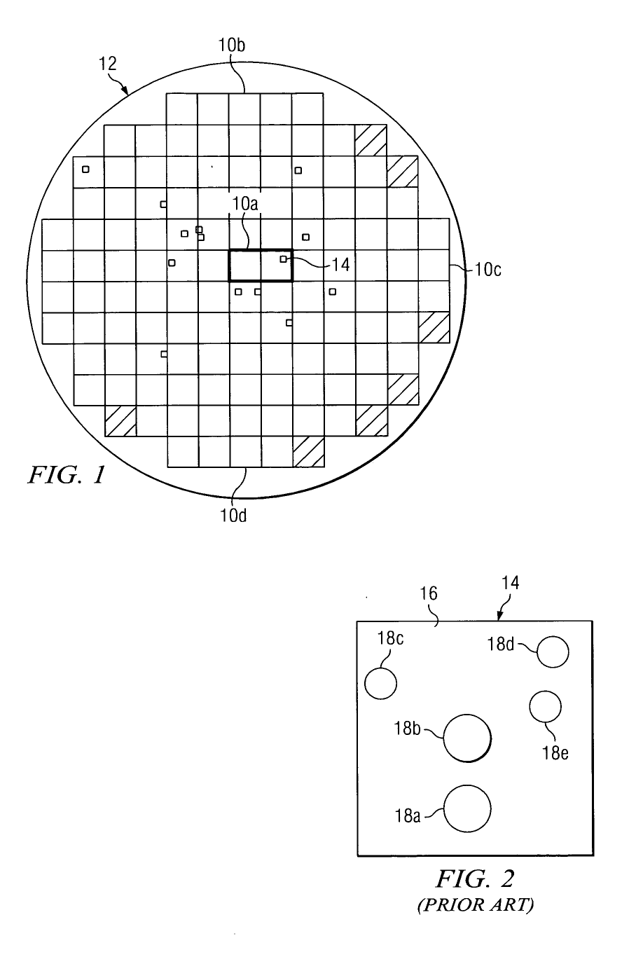

Referring now to FIG. 1, there is illustrated a typical layout of about 122 integrated circuits, such as 10a, 10b, 10c and 10d, on a silicon wafer 12. As was discussed above, adding oxide and/or metal films on top of silicon wafer always causes some stress in the structure (oxide films typically cause compressive stress and metal films typically cause tensile stress). As was also discussed, processing steps such as CMP (chemical milling processing) or fabricating tungsten (W) plugs as interconnecting lines between multiple layers of circuits in an IC (integrated circuit) results in an unacceptable number of tungsten plug “pullouts” or “pull-ups” in the chips processed on a 300 μm wafer whereas such “pull-outs” are not a major concern when the CMP is with respect to a smaller 200 μm wafer.

Referring again to FIG. 1, there is illustrated a small square 14 on chip 10a. FIG. 2 is a drawing representing an enlarged photograph of the small square 14 of integrated circuit chip 10a. FIG. 2 shows a surface 16 with five (5) tungsten plugs 18a, 18b, 18c, 18d and 18e. As can be seen, plug 18b has pulled out of its aperture and represents a chip failure. The process of the present invention helps to eliminate or substantially reduce failure of the chips due to metal plug pullout.

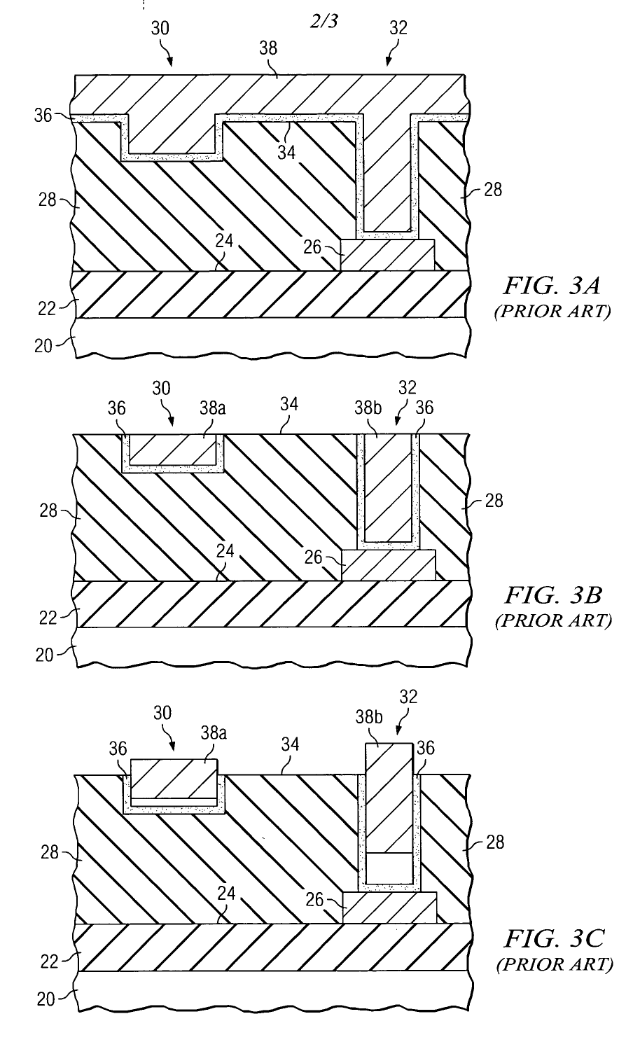

Referring to FIG. 3A, there is a blown-up cross-sectional illustration of the processing steps of fabricating a tungsten plug as used to interconnect circuit levels in an IC. As shown, a wafer 20 contains one or more ILD layers 22 (intermediate level dielectric). Each layer of the ILD may include electronic circuits and/or levels of metallization. The top surface 24 of the ILD 22 is shown as including a metal contact pad 26 which may be made of any suitable metal, such as for example only, aluminum, copper, and alloy of aluminum and copper or even exotic metals such as silver and gold, etc. A layer 28 of selected material, such as a dielectric material or an insulating material, is deposited over the top surface 24 of the ILD 22 and the contact pad 26. In the embodiment of the prior art FIG. 3A, a trench 30 and a via 32 are defined in the selected material 28. As will be appreciated by those skilled in the art, the trench 30 is defined in the top surface 34 of the material 28 and will be filled with a conductive metal to form connecting lines of metallization. The via 32 extends from the top surface 34 through the selected material 28 to the contact pad 26 for providing an interconnect between circuits in the ILD 22 and any circuits or connections formed on the top surface 34 of selected material 28. A liner or glue material 36 typically coats the bottom and sidewalls of the trench and vias, as well as top surface 34 of the selected material 28, but may be eliminated for some applications. Materials suitable for use as the liner or glue material 36 include, as examples only, tantalum, tantalum nitride, titanium and titanium nitride. Tungsten (W) is then deposited over the substrate so as to overfill the trench 30 and via 32 and to form a layer 38 of tungsten over the semiconductor structure.

FIG. 3B illustrates the chemical milling prior art process of removing the tungsten layer and the liner material 36 down to the top surface 34 of the selected material 28 to leave a trench 30 filled with tungsten 38a and via 32 filled with tungsten 38b. FIG. 3C illustrates a typical example of “pullout” of the lines of metallization 38a and the plug 30b typically occurring during the CMP process causing chip failure.

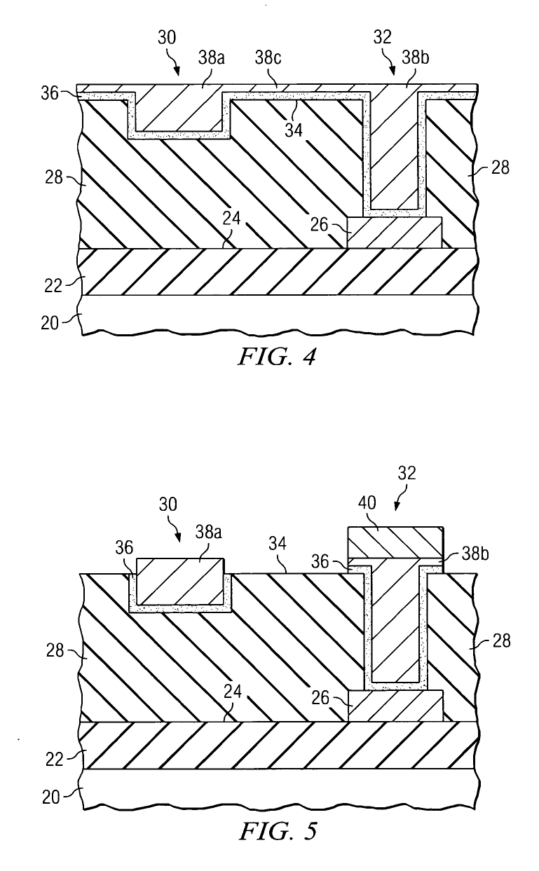

To overcome these problems, the present invention follows the prior art processes to fabricate the structure such as shown in FIG. 3A. However, instead of chemical mill processing the tungsten 38 and liner material 36 down to the top surface 34 of selected material 28, according to the present invention the CMP is stopped so as to leave the liner material, if used, and a thin film or layer 38c of between about 0.3 μm and 0.01 μm of tungsten as shown in FIG. 4. Contact pad 40 is then deposited, marked and etched to produce the structure of FIG. 5. Controlling the partial CMP step so as to leave the thin layer 38c of tungsten significantly reduces the “pullout” of tungsten plugs and lines of metallization and consequently chip failure.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, methods and steps described in the specification. As one of ordinary skill in the art will readily appreciate from the disclosure of the present invention, processes, methods, or steps, presently existing or later to be developed, that perform substantially the same function or achieve substantially the same result as the corresponding embodiments described herein may be utilized according to the present invention. Accordingly, the appended claims are intended to include within their scope such processes, methods, or steps.

1. A method of reducing the circuit failure caused by tungsten plug pulling out of an apparatus comprising the steps of:
providing a substrate having a lower portion and a layer of selected material over said lower portion, said selected material having a top surface;
defining an aperture in said selected material extending from said top surface toward said lower portion;
depositing a layer of tungsten over said top surface of said layer of selected material, said tungsten also filling said aperture;
polishing said tungsten layer to remove a top portion of said tungsten layer;
stopping said polishing so as to leave a reduced thickness of said tungsten layer; and
providing a contact area over at least a portion of said tungsten filled aperture, said contact area in electrical contact with said tungsten filling said aperture.

2. The method of claim 1 wherein said aperture is a trench.

3. The method of claim 1 wherein said substrate further includes a conductive area covered by said layer of selected material and wherein said aperture is a via extending through said layer of selected material and said tungsten in said via is in electrical contact with said conductive area.

4. The method of claim 1 wherein said reduced layer of tungsten remaining after polishing is between 0.3 μm and 0.01 μm.

5. The method of claim 1 wherein said layer of selected material is one of a layer of a dielectric material and a layer of insulating material.

6. The method of claim 1 further comprising the step of depositing a liner material in said aperture and over said top surface of said selected material before depositing said layer of tungsten.

7. The method of claim 3 wherein said contact area is made of a conductive material selected from the group consisting of copper, aluminum and an alloy of copper and aluminum.

8. The method of claim 3 wherein said conductive area is made of a conductive material selected from the group consisting of copper, aluminum and an alloy of copper and aluminum.

9. The method of claim 8 wherein said contact area is made of a conductive material selected from the group consisting of copper, aluminum and an alloy of copper and aluminum.

10. The method of claim 6 wherein said liner material is selected from the group consisting of tantalum, tantalum nitride, titanium, and titanium nitride.

11-20. Cancelled

21. A method of reducing integrated circuit failures in an integrated circuit chip caused by metal plug pull-ups and pull-outs while making said chip, said method comprising:
forming an aperture in a top surface of a selected material layer, said selected material layer being formed over a wafer, wherein said aperture extends toward said wafer from said top surface;
depositing a layer of metal over said top surface of said selected material layer and into said aperture to fill said aperture with metal;
polishing said metal layer to remove a top portion of said metal layer;
stopping said polishing to leave a reduced thickness portion of said metal layer adjacent to said aperture;
forming a contact pad at least partially over said metal filled aperture; and
removing at least part of said reduced thickness portion of said metal layer during said forming of said contact pad.

22. The method of claim 21, wherein the metal comprises tungsten.

23. The method of claim 21 wherein said reduced thickness portion of said metal layer has a thickness between about 0.3 μm and 0.01 μm.

24. The method of claim 21 wherein said wafer has a diameter greater than 200 mm.

25. The method of claim 21 wherein said selected material layer comprises a dielectric material.

26. The method of claim 21 further comprising:
depositing a liner material layer in said aperture and over said top surface of said selected material layer before depositing said metal layer, wherein said metal layer is formed over said liner material layer.

27. A method of making an integrated circuit chip, the method comprising:
forming an aperture in a top surface of a selected material layer, said selected material layer being formed over a wafer, wherein said aperture extends toward said wafer from said top surface;
depositing a layer of metal over said top surface of said selected material layer and into said aperture to fill said aperture with metal;
polishing said metal layer to remove a top portion of said metal layer;
stopping said polishing to leave a reduced thickness portion of said metal layer adjacent to said aperture;
forming a contact pad at least partially over said metal filled aperture; and
removing at least part of said reduced thickness portion of said metal layer during said forming of said contact pad.

28. The method of claim 27, wherein the metal comprises tungsten.

29. The method of claim 27 wherein said reduced thickness portion of said metal layer has a thickness between about 0.3 μm and 0.01 μm.

30. The method of claim 27 wherein said wafer has a diameter greater than 200 mm.

31. The method of claim 27 wherein said selected material layer comprises a dielectric material.

32. The method of claim 27 further comprising:
depositing a liner material layer in said aperture and over said top surface of said selected material layer before depositing said metal layer, wherein said metal layer is formed over said liner material layer.
